(19) United States
(12) Patent Application Publication
(10) Pub. No.: US 2026/0110600 A1
(43) Pub. Date: Apr. 23, 2026

(54) ANALYSIS APPARATUS AND ANALYSIS METHOD

(71) Applicant: Tokyo Electron Limited, Tokyo (JP)

(72) Inventors: Toshiyuki FUKUMOTO, Yamanashi (JP); Huizhen BU, Tokyo (JP); Yuichi TAKENAGA, Yamanashi (JP); Yuka NAKASATO, Yamanashi (JP); Tetsushi YANO, Yamanashi (JP)

(21) Appl. No.: 19/429,007

(22) Filed: Dec. 22, 2025

Related U.S. Application Data
(63) Continuation of application No. PCT/JP2024/023225, filed on Jun. 26, 2024.

(30) Foreign Application Priority Data
Jul. 10, 2023 (JP) 2023-113301

(51) Int. Cl. G01M 99/00; H10P 72/00

(52) U.S. Cl. CPC G01M 99/005; H10P 72/0604

(57) ABSTRACT

An analysis device includes a processor; and a memory storing program instructions that cause the processor to divide log data of each of sensors of sensor groups for detecting states of each of a plurality of substrate processing apparatuses into segments and store the log data divided for each of the segments in a data storage unit for each of the sensors; perform an analysis on an inter-apparatus difference between the plurality of substrate processing apparatuses by analyzing each of the plurality of substrate processing apparatuses based on the log data divided for each of the segments stored in the data storage unit; and display a result of the analysis.

### CROSS-REFERENCE TO RELATED APPLICATIONS

This application is a continuation application of International Application No. PCT/JP2024/023225 filed on Jun. 26, 2024, and designating the U.S., which is based upon and claims priority to Japanese Patent Application No. 2023-113301, filed on Jul. 10, 2023, the entire contents of which are incorporated herein by reference.

### BACKGROUND

### 1. Technical Field

The present disclosure relates to an analysis apparatus and an analysis method.

### 2. Description of the Related Art

For example, Patent Document 1 proposes an information processing system including a temperature measurement unit configured to measure a temperature distribution in an array direction of substrates to be processed; a simulation execution unit configured to execute a simulation of a temperature distribution during heat treatment of the substrates to be processed in a processing chamber by using a standard or individual simulation model; a model correction unit configured to correct the standard simulation model to an individual simulation model based on a difference between the measured temperature distribution and the temperature distribution obtained as a result of the simulation; and a correction unit configured to correct a target temperature by using the temperature distribution obtained as a result of the simulation using the individual simulation model.

For example, Patent Document 2 proposes an information calculation device including a learning determination unit configured to determine whether to update a model for generating temperature correction information in which a temperature correction value is associated with a cumulative film thickness; a model learning unit configured to update the model based on a film formation result on an object to be processed when it is determined that the model is to be updated; and a temperature correction information generation unit configured to generate temperature correction information by using the model updated by the model learning unit and correct a set temperature based on the temperature correction information.

### RELATED ART DOCUMENT

### Patent Document

Patent Document 1: Japanese Laid-Open Patent Application Publication No. 2022-168572
Patent Document 2: Japanese Laid-Open Patent Application Publication No. 2022-187915

### SUMMARY

According to one embodiment of the present disclosure, an analysis device includes a processor; and a memory storing program instructions that cause the processor to divide log data of each of sensors of sensor groups for detecting states of each of a plurality of substrate processing apparatuses into segments and store the log data divided for each of the segments in a data storage unit for each of the sensors; perform an analysis on an inter-apparatus difference between the plurality of substrate processing apparatuses by analyzing each of the plurality of substrate processing apparatuses based on the log data divided for each of the segments stored in the data storage unit; and display a result of the analysis.

### BRIEF DESCRIPTION OF THE DRAWINGS

FIG. 1 is a schematic sectional view illustrating an example of a substrate processing apparatus according to an embodiment;

FIG. 2 is a configuration diagram illustrating an example of a substrate processing system according to the embodiment;

FIG. 3 is a diagram illustrating an example of a hardware configuration of the information processing apparatus according to the embodiment;

FIG. 4 is a diagram illustrating an example of a functional configuration of the information processing apparatus according to the embodiment;

FIG. 5 is a flowchart illustrating an example of preprocessing according to the embodiment;

FIGS. 6A, 6B, and 6C are diagrams illustrating an example of log data divided into segments during preprocessing;

FIG. 7 is a graph illustrating an example of log data divided into segments during preprocessing;

FIG. 8 is a diagram illustrating an example of abnormality determination based on analysis results for each analysis level;

FIG. 9 is a diagram illustrating an example of abnormality determination based on analysis results for each analysis level;

FIG. 10 is a flowchart illustrating an example of an analysis method according to the embodiment;

FIG. 11 is a flowchart illustrating an analysis process in step S14 of FIG. 10 in detail;

FIG. 12 is a diagram illustrating a display example of the analysis results;

FIG. 13 is a diagram illustrating a display example of the analysis results;

FIG. 14 is a diagram illustrating a display example of the analysis results;

FIG. 15 is a diagram illustrating a display example of the analysis results;

FIG. 16 is a diagram illustrating a display example of the analysis results; and

FIG. 17 is a diagram illustrating a score display example of the analysis results.

### DETAILED DESCRIPTION

Hereinafter, an embodiment of the present disclosure will be described with reference to the accompanying drawings. In each of the drawings, the same components are denoted by the same reference numerals, and duplicated descriptions may be omitted.

### Substrate Processing Apparatus

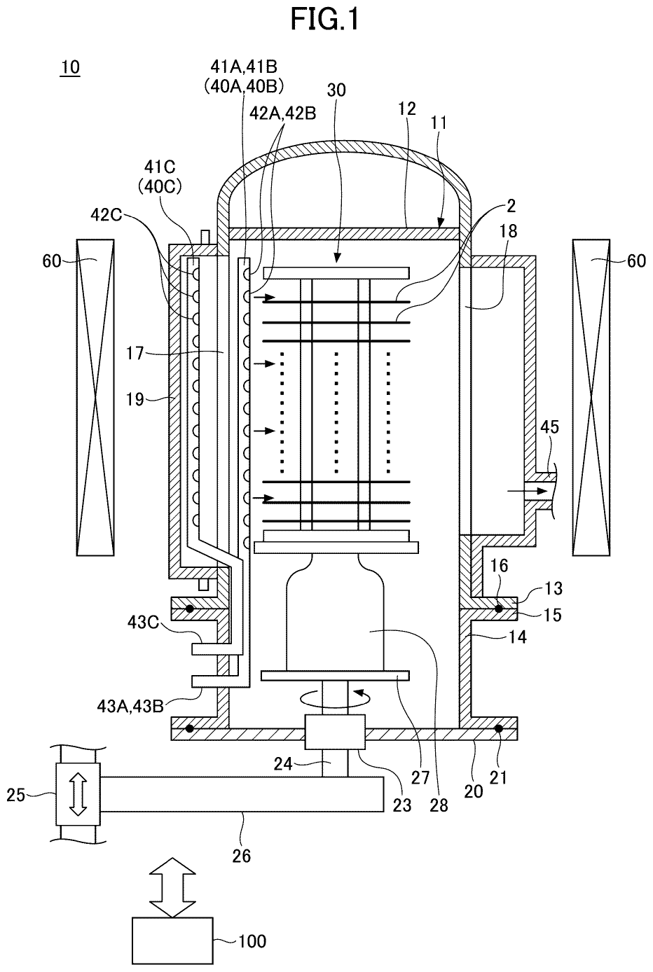

A batch-type substrate processing apparatus configured to perform a desired film formation process on a plurality of substrates will be described with reference to FIG. 1. FIG. 1 is a schematic cross-sectional view illustrating an example of a substrate processing apparatus 10 according to an embodiment. The substrate processing apparatus 10 accommodates a plurality of wafers 2 in a processing chamber 11 and simultaneously forms films on the plurality of wafers.

The substrate processing apparatus 10 is a batch-type vertical heat treatment apparatus configured to process the plurality of wafers 2. The substrate processing apparatus 10 includes the processing chamber 11 configured to accommodate the wafers 2 and forming a space in which the wafers 2 are processed, a cover 20 configured to airtightly close an opening at the lower end of the processing chamber 11, and a boat 30 configured to hold the wafers 2. The wafers 2 are, for example, semiconductor substrates (which are also referred to simply as “substrates”) and, for example, silicon wafers.

The processing chamber 11 includes a main body 12 of a cylindrical processing chamber having a ceiling and an open lower end. The main body 12 of the processing chamber is formed of, for example, quartz. A flange 13 is formed at the lower end of the main body 12 of the processing chamber. Additionally, the processing chamber 11 includes, for example, a cylindrical manifold 14. The manifold 14 is formed of, for example, stainless steel. A flange 15 is formed at the upper end of the manifold 14, and the flange 13 of the main body 12 of the processing chamber is installed on the flange 15. A seal member 16 such as an O-ring is disposed between the flange 15 and the flange 13.

The cover 20 is airtightly attached to an opening of the manifold 14 at the lower end thereof through a seal member 21 such as an O-ring. The cover 20 is formed of, for example, stainless steel. A through hole vertically penetrating the cover 20 is formed in a central portion of the cover 20. A rotary shaft 24 is disposed in the through hole. A gap between the cover 20 and the rotary shaft 24 is sealed by a magnetic fluid seal 23. A lower end portion of the rotary shaft 24 is rotatably supported by an arm 26 of a raising and lowering section 25. A rotary plate 27 is provided at an upper end portion of the rotary shaft 24. The boat 30 is installed on the rotary plate 27 via a temperature retaining stage 28.

The boat 30 holds the plurality of wafers 2 in the vertical direction. For example, in the boat 30 configured to hold 200 wafers 2, slots given a slot number of 1 to 200 are arranged in the vertical direction. By arranging the wafers 2 in the respective slots, the plurality of wafers 2 are held at intervals horizontally. The boat 30 is formed of, for example, quartz (SiO₂) or silicon carbide (SiC). When the raising and lowering section 25 is raised, the cover 20 and the boat 30 are raised, the boat 30 is carried into the processing chamber 11, and the opening at the lower end of the processing chamber 11 is sealed by the cover 20. When the raising and lowering section 25 is lowered, the cover 20 and the boat 30 are lowered, and the boat 30 is carried out to the outside of the processing chamber 11. Additionally, when the rotary shaft 24 is rotated, the boat 30 is rotated together with the rotary plate 27.

The substrate processing apparatus 10 includes three gas supply pipes 40A, 40B, and 40C. The gas supply pipes 40A, 40B, and 40C are formed of, for example, quartz (SiO₂). The gas supply pipes 40A, 40B, and 40C supply gas into the processing chamber 11. The kinds of gases will be described later. Here, one gas supply pipe may discharge one kind of gas or a plurality of kinds of gases in order. A plurality of gas supply pipes may discharge the same kind of gas.

The gas supply pipes 40A, 40B, and 40C include horizontal pipes 43A, 43B, and 43C horizontally penetrating the manifold 14 and vertical pipes 41A, 41B, and 41C vertically arranged inside the processing chamber 11. The vertical pipes 41A, 41B, and 41C have a plurality of air supply ports 42A, 42B, and 42C at intervals in the vertical direction. Various gases supplied to the horizontal pipes 43A, 43B, and 43C are sent to the vertical pipes 41A, 41B, and 41C and discharged horizontally from the plurality of air supply ports 42A, 42B, and 42C. The vertical pipe 41C is disposed inside a plasma box 19. The vertical pipes 41A and 41B are disposed inside the processing chamber 11.

The substrate processing apparatus 10 includes an exhaust pipe 45. The exhaust pipe 45 is connected to an exhaust device (which is not illustrated). The exhaust device includes a vacuum pump and exhausts the inside of the processing chamber 11. To exhaust the inside of the processing chamber 11, an exhaust port 18 is formed in the main body 12 of the processing chamber. The exhaust port 18 is arranged to face the air supply ports 42A, 42B and 42C. The gases horizontally discharged from the air supply ports 42A, 42B and 42C pass through the exhaust port 18 and then are discharged from the exhaust pipe 45. The exhaust device sucks the gas inside the processing chamber 11 and sends it to a purification device. The purification device discharges the exhaust gas to the atmosphere after removing harmful components of the exhaust gas.

The substrate processing apparatus 10 further includes a heating section 60. The heating section 60 is disposed outside the processing chamber 11 and heats the inside of the processing chamber 11 from the outside of the processing chamber 11. For example, the heating section 60 is formed in a cylindrical shape to surround the main body 12 of the processing chamber. The heating section 60 includes, for example, a heater. The heating section 60 heats the inside of the processing chamber 11 to improve the processing capability of the gas supplied into the processing chamber 11.

An opening 17 is formed in a portion of the main body 12 of the processing chamber in the circumferential direction. The plasma box 19 is formed on the side surface of the processing chamber 11 to surround the opening 17. The plasma box 19 is formed to project radially outward from the main body 12 of the processing chamber, and is formed, for example, in a U-shape when viewed in the vertical direction.

A pair of electrodes is arranged to sandwich the plasma box 19. The pair of electrodes is a pair of parallel electrodes arranged to face the external side of the plasma box 19. Similar to the vertical pipe 41C, the pair of electrodes is formed to face each other and to be elongated in the vertical direction. The pair of electrodes is connected to an RF power supply via a matching device, and a high-frequency voltage is applied from the RF power supply.

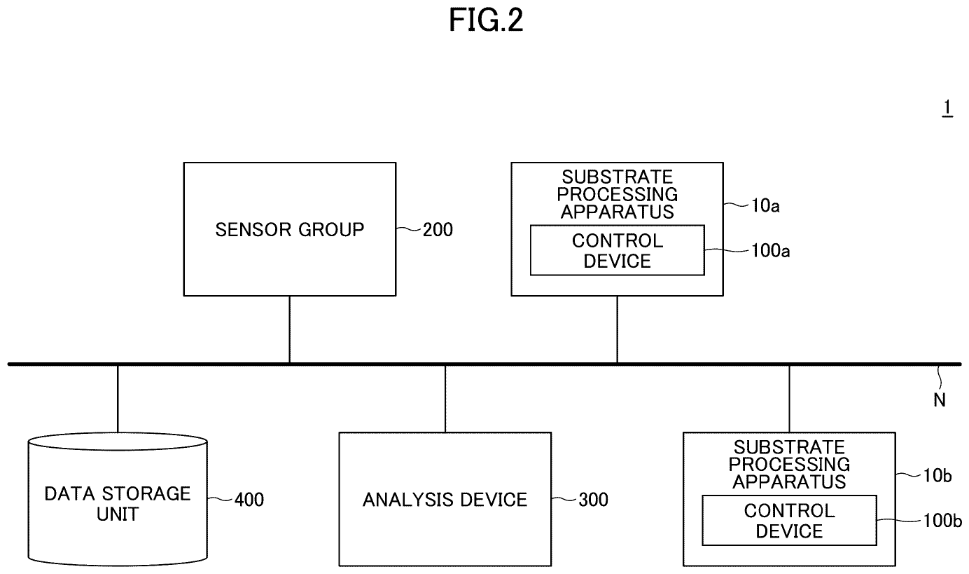

The substrate processing apparatus 10 includes a controller 100. The controller 100 processes computer-executable instructions that cause the substrate processing apparatus 10 to perform various substrate processing steps. The controller 100 may be configured to control elements of the substrate processing apparatus 10 to perform various substrate processing steps. In one embodiment, some or all of the controller 100 may be included in the substrate processing apparatus 10. The controller 100 may include a processing unit, a data storage unit, and a communication interface. The controller 100 may be implemented, for example, by a computer. The processing unit may be configured to perform various control operations by reading recipes and programs from the data storage unit and executing the read recipes and programs. The recipes and programs may be stored in advance in the data storage unit or may be retrieved via a medium when necessary. The medium may be any storage medium readable by a computer or a communication line connected to the communication interface. The processing unit may be a central processing unit (CPU). The data storage unit may be a random access memory (RAM), a read only memory (ROM), a hard disk drive (HDD), or the like. The communication interface may communicate between the substrate processing apparatus 10, the sensor group 200, and an analysis device 300 (see FIG. 2) via a communication network such as a LAN.

### Substrate Processing System

Next, a substrate processing system 1 will be described with reference to FIG. 2. FIG. 2 is a configuration diagram illustrating an example of the substrate processing system 1 according to the embodiment. The substrate processing system 1 includes substrate processing apparatuses 10a and 10b, a sensor group 200, an analysis device 300, and a data storage unit 400, and these are connected to each other via a communication network N, such as the Internet or LAN, to enable data communication. A controller 100a is incorporated in the substrate processing apparatus 10a. A controller 100b is incorporated in the substrate processing apparatus 10b. Although two substrate processing apparatuses are illustrated, three or more substrate processing apparatuses may be provided. The substrate processing apparatuses 10a and 10b are examples of the substrate processing apparatus 10. The controllers 100a and 100b are examples of the controller 100.

A plurality of sensors are attached to each of the plurality of substrate processing apparatuses 10. The sensor group 200 attached to each of the plurality of substrate processing apparatuses 10 includes a film thickness sensor, a temperature sensor, a humidity sensor, a pressure sensor, a vibration sensor, a distance sensor, and the like. The sensor group 200 is not limited to the above-mentioned types of sensors as long as the sensor detects the state of each of the plurality of substrate processing apparatuses 10.

The sensor group 200 may be included in the substrate processing apparatuses 10a and 10b, may be directly connected to the substrate processing apparatuses 10a and 10b, or may be connected to the substrate processing apparatuses 10a and 10b via the communication network N.

As illustrated in FIG. 1, the substrate processing apparatus 10 carries the boat 30, on which the plurality of wafers 2 are mounted, into the processing chamber 11 to form films on the plurality of wafers 2. “Run” (substrate processing) may indicate that the boat 30 is carried into the processing chamber 11 and film forming processing is simultaneously performed on the plurality of wafers 2.

Log data of sensor values measured by the sensor group 200 is time-series data and is stored in the data storage unit 400. The analysis device 300 acquires necessary log data from the data storage unit 400 and uses it for analyzing the inter-apparatus difference of the plurality of substrate processing apparatuses 10. As will be described later, preprocessing for dividing the log data is performed before analysis. The analysis device 300 divides the log data into segments for each of the sensors of each of the substrate processing apparatuses 10 and analyzes each of the substrate processing apparatuses 10 based on the log data for each of the segments to analyze the inter-apparatus difference between the plurality of substrate processing apparatuses.

In the conventional method for analyzing the inter-apparatus difference (the individual difference) between the substrate processing apparatuses and a state change before and after maintenance of the substrate processing apparatus, an expert having knowledge of the substrate processing apparatuses performs an analysis after narrowing down sensors to be analyzed from among sensors of the substrate processing apparatuses to some extent. Correction values of process conditions such as a heat treatment set temperature are calculated using machine learning on time-series data and summary data of the sensors that are narrowed down, and are reflected in the set temperatures.

For this reason, when analyzing the individual difference of the substrate processing apparatuses or the state change of the substrate processing apparatus in a situation where the cause cannot be identified, it is necessary for an expert of the substrate processing apparatuses to narrow down the sensors to some extent. Additionally, although there is a conventional method for analyzing the inter-apparatus difference specialized to a specific sensor such as a temperature sensor, there is no method for comprehensively analyzing the entire sensors configured to detect the states of the substrate processing apparatuses and analyzing the inter-apparatus difference for each of the substrate processing apparatuses.

In the analysis device 300 according to the present embodiment, the entire sensor group 200 of the plurality of substrate processing apparatuses 10 can be comprehensively analyzed without narrowing down the sensors to be analyzed. Then, an analysis result can be visualized and displayed as a graph, a table, or the like. By checking the graph or the like indicating the trend of the output value, the expert can identify the defective part or sensor.

Furthermore, not only the output values of the specific sensor but also the output values of the sensor group 200 of the substrate processing apparatus 10 can be collectively analyzed (inter-apparatus difference analysis). With this, it becomes unnecessary for the expert having knowledge to narrow down the sensors to be analyzed from among the sensors of the substrate processing apparatus, thereby reducing the load of the expert and allowing human resources to be transferred to other work.

### Hardware Configuration

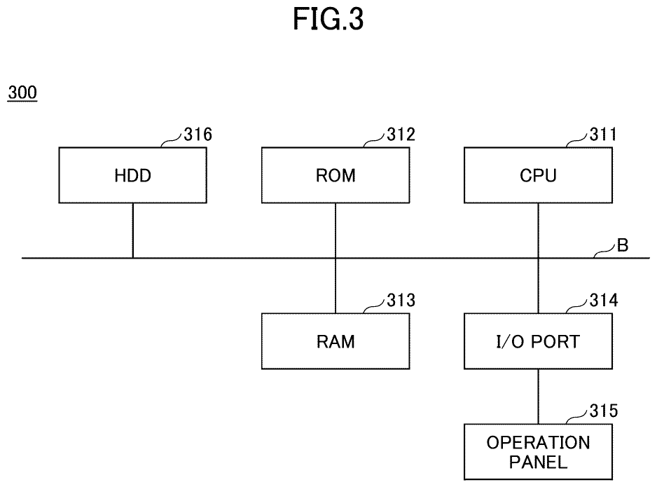

The analysis device 300 is implemented by a computer having a hardware configuration illustrated in FIG. 3, for example. FIG. 3 is a diagram illustrating an example of a hardware configuration of the analysis device 300 according to the embodiment. The analysis device 300 includes, for example, a computer including a CPU 311, a ROM 312, and a RAM 313. Additionally, the analysis device 300 includes an I/O port 314, an operation panel 315, and an HDD 316. The respective elements are connected by a bus B.

The CPU 311 is an arithmetic unit configured to read programs and data from storage devices, such as the ROM 312 and the HDD 316, into the RAM 313 and execute substrate processing, thereby realizing control and functions of the entire analysis device 300.

The ROM 312 includes an electrically erasable programmable ROM (EEPROM), a flash memory, a hard disk, and the like, and is a storage medium for storing programs used by the CPU 311. The RAM 313 functions as a work area or the like of the CPU 311. The programs used by the CPU 311 include a program for executing a display method described later.

The I/O port 314 acquires a measured value such as a film thickness measured by the sensor group 200 and transmits it to the CPU 311. The I/O port 314 is connected to the operation panel 315 on which a user operates the analysis device 300.

The HDD 316 is an auxiliary storage device and may store programs or the like. The HDD 316 may store log data measured by the sensor group 200.

### Functional Configuration

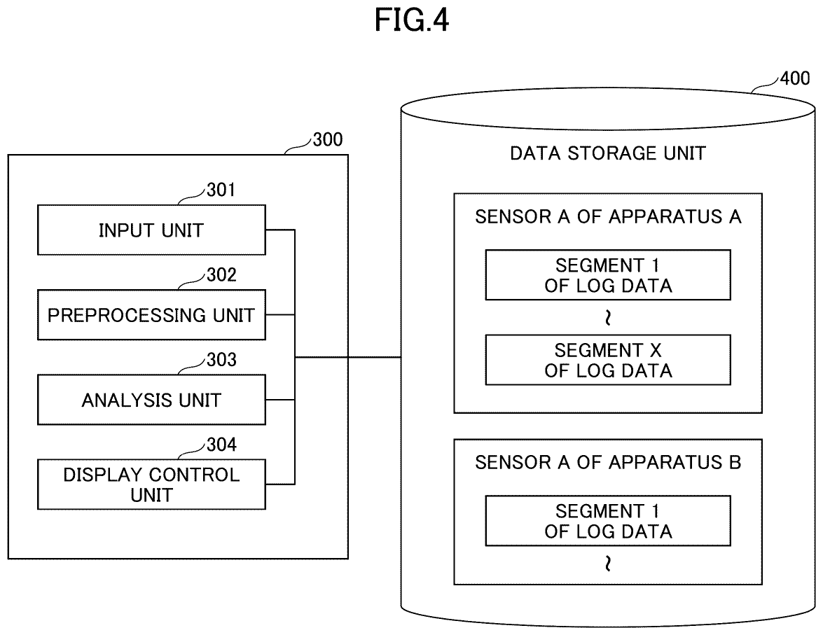

Next, a functional configuration of the analysis device 300 will be described with reference to FIG. 4. FIG. 4 illustrates an example of the functional configuration of the analysis device 300 according to the embodiment. The analysis device 300 includes an input unit 301, a preprocessing unit 302, an analysis unit 303, and a display control unit 304.

The input unit 301 inputs log data of a plurality of sensor values measured by the sensor group 200 configured to detect the states of each of the plurality of substrate processing apparatuses 10. The sensor values may be time-series data.

The preprocessing unit 302 divides the log data of each of the sensors of the sensor group 200 configured to detect the states of each of the plurality of substrate processing apparatuses 10 into segments, and stores the log data for each of the segments in the data storage unit 400 for each of the sensors.

The analysis unit 303 analyzes each of the substrate processing apparatuses 10 based on the log data for each of the segments stored in the data storage unit 400 to analyze the inter-apparatus difference between the plurality of substrate processing apparatuses.

The display control unit 304 displays analysis results obtained by the analysis of the analysis unit 303. The display control unit 304 may display the analysis results of the inter-apparatus difference as a graph or table according to an analysis level. The analysis level and the graph of the analysis result will be described later.

Here, the input unit 301 is implemented by, for example, the operation panel 315 and the I/O port 314. The preprocessing unit 302, the analysis unit 303, and the display control unit 304 are implemented by, for example, the CPU 311. The data storage unit 400 may be disposed inside the analysis device 300, and in this case, it is implemented by, for example, the ROM 312, the RAM 313, and the HDD 316.

### Preprocessing Method

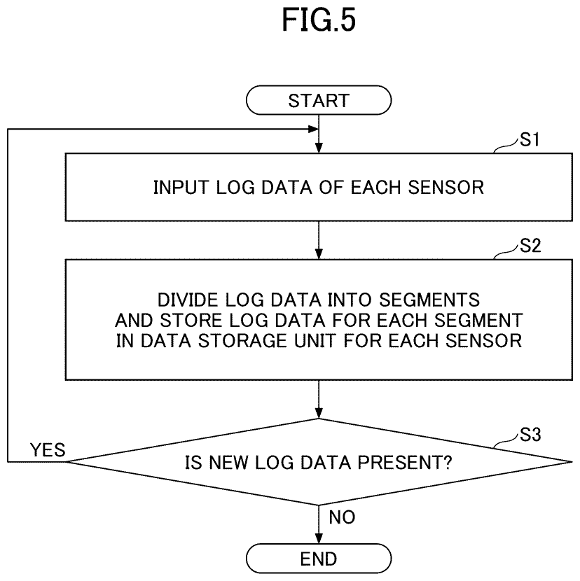

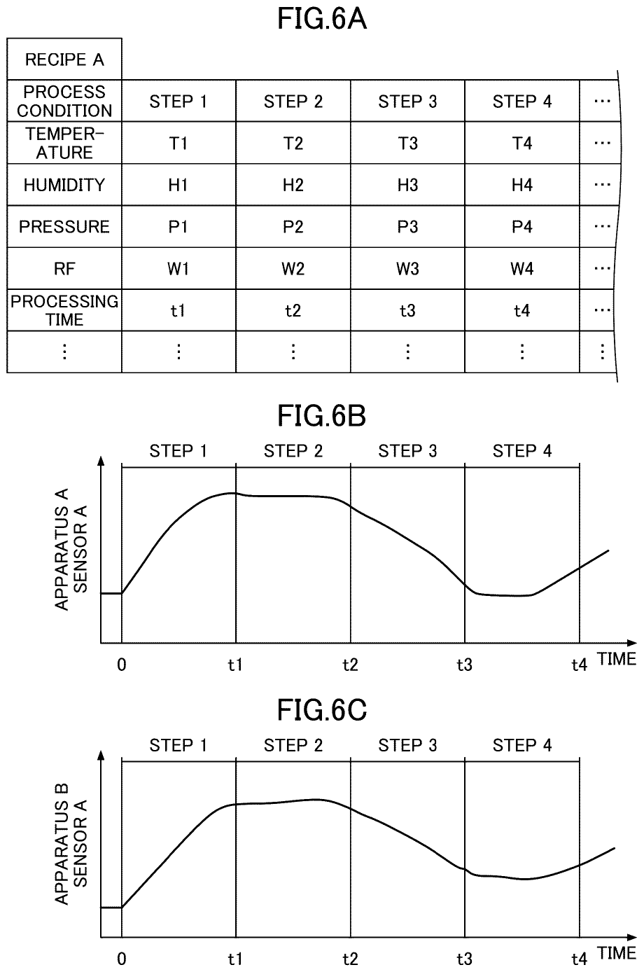

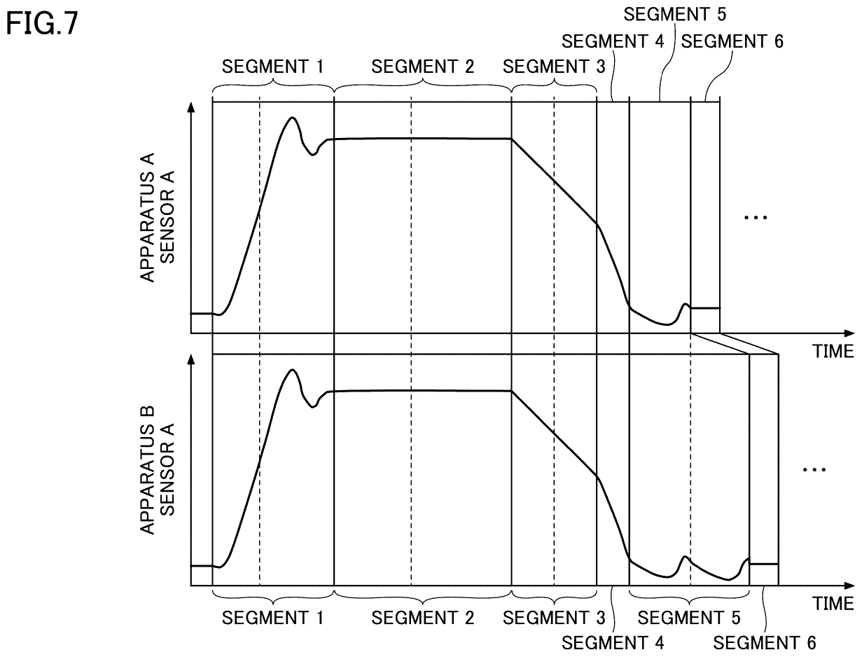

Next, a preprocessing method according to the embodiment will be described with reference to FIGS. 5 to 7. FIG. 5 is a flowchart illustrating an example of the preprocessing method according to the embodiment. FIGS. 6A, 6B, 6C, and 7 are diagrams illustrating an example of log data for each of the segments divided during preprocessing. The preprocessing method according to the present embodiment is performed by the analysis device 300.

This processing is automatically started after the boat 30 on which the plurality of wafers 2 are mounted is carried into the processing chamber 11 and the film forming of the plurality of wafers 2 is performed. First, in step S1, the preprocessing unit 302 inputs the log data of each of the sensors of the sensor group 200 configured to detect the states of each of the substrate processing apparatuses 10 via the communication network N.

Next, in step S2, the preprocessing unit 302 divides the log data of each of the sensors into segments and stores the log data for each of the segments in the data storage unit 400 for each of the sensors. As a method for dividing the log data of each of the sensors into the segments, there are a method for dividing the log data into static segments and a method for dividing the log data into dynamic segments.

A method for dividing log data of each of the sensors into static segments will be described with reference to FIGS. 6A, 6B, and 6C. For example, the recipe A illustrated in FIG. 6A is assumed to be a recipe indicating a procedure of a process performed by the substrate processing apparatus 10 to which a sensor that detects the input log data is attached, among recipes indicating steps of procedures of processes performed by the plurality of substrate processing apparatuses 10.

The preprocessing unit 302 divides the log data of each of the sensors for each of the steps by setting the processing time of each of the steps set in the recipe A as a period used to divide the log data into segments. That is, in the method for dividing the log data into static segments, the log data for each of the segments is log data divided for each of the steps of the recipe.

For example, a waveform of log data of a sensor value detected by a sensor A of a substrate processing apparatus A illustrated in FIG. 6B is automatically divided into log data for a step 1, log data for a step 2, log data for a step 3, and log data for a step 4 of the recipe A by the preprocessing unit 302.

Similarly, a waveform of log data of a sensor value detected by a sensor A of a substrate processing apparatus B illustrated in FIG. 6C is divided into log data for a step 1, log data for a step 2, log data for a step 3, and log data for a step 4 of the recipe A by the preprocessing unit 302. When a process using the same recipe A is performed in different substrate processing apparatuses A and B, the log data of the sensor value detected by the same type of sensor A in each of the substrate processing apparatuses A and B tends to have the same or substantially the same waveform in the same step. This is because, as illustrated in FIG. 6A, in the same step of the same recipe, process conditions, such as the temperature, the humidity, and the pressure, are the same, so that environments in the substrate processing apparatuses A and B are almost the same. In other words, in the same step of the same recipe, among the log data of each of the sensors of the substrate processing apparatuses A and B for each step, if there is a step in which the inter-apparatus difference between the substrate processing apparatuses A and B is larger than a threshold value, it can be determined that there is a possibility that an abnormality occurs in either of the substrate processing apparatuses A and B in that step.

A method for dividing log data of each of the sensors into dynamic segments will be described with reference to FIG. 7. For example, a waveform of log data of a sensor value detected by the sensor A of the substrate processing apparatus A illustrated in FIG. 7 is automatically divided into log data for a segment 1, a segment 2, a segment 3, a segment 4, a segment 5, and a segment 6 by the preprocessing unit 302. A waveform of log data of a sensor value detected by the sensor A of the substrate processing apparatus B is automatically divided into log data for a segment 1, a segment 2, a segment 3, a segment 4, a segment 5, and a segment 6 by the preprocessing unit 302. The log data for the segment 1, the segment 2, the segment 3, and the segment 4 are log data of the same time period, but the log data for the segment 5 and the segment 6 are log data of different time periods, and it is found that the log data are dynamically divided and segmented.

In the example of FIG. 7, the preprocessing unit 302 extracts the features of the waveform of the log data of each of the sensors, and divides the log data for each of the features of the waveform. With this, the log data of each of the sensors can be divided into segments. The features of the waveform include slope, constant, vibration, and the like. In the case of dividing the log data for each of the segments as illustrated in FIG. 7, the number of variables is reduced in comparison with the case of dividing the log data for each of the steps in FIGS. 6A, 6B, and 6C, and only statistical quantities suitable for analysis can be extracted, and thus it is expected to improve the accuracy of analysis. Here, the log data for each of the steps is an example of the log data for each of the segments.

As a result, as illustrated in FIG. 4, the log data for each of the segments (log data for the segment 1 to log data for the segment x (x is an integer)) is stored in the data storage unit 400 for each of the substrate processing apparatuses (apparatus A, apparatus B, . . . ) and for each of the sensors (sensor A, sensor B, . . . ).

### Outline of Analysis Method

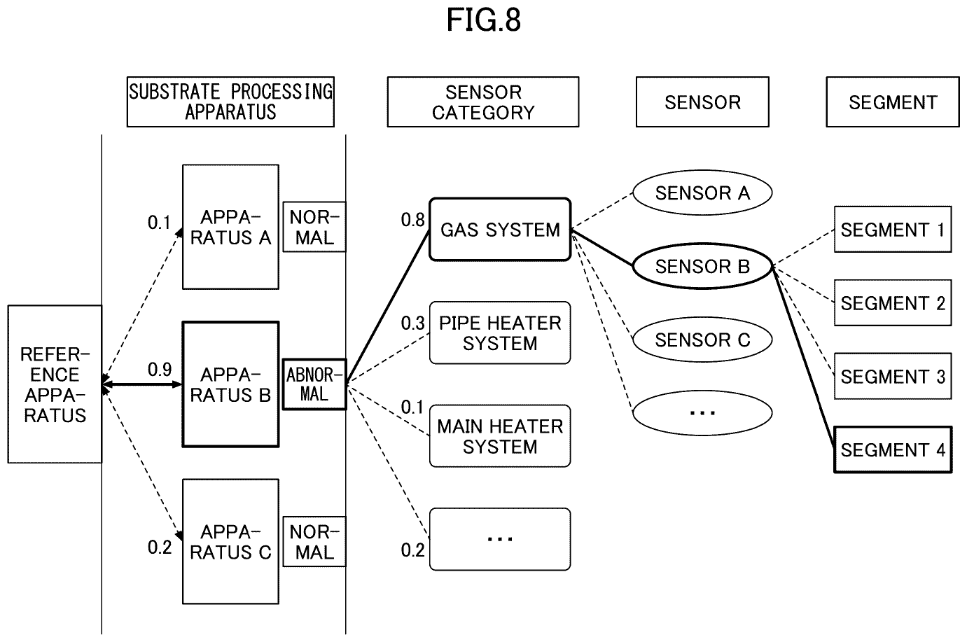

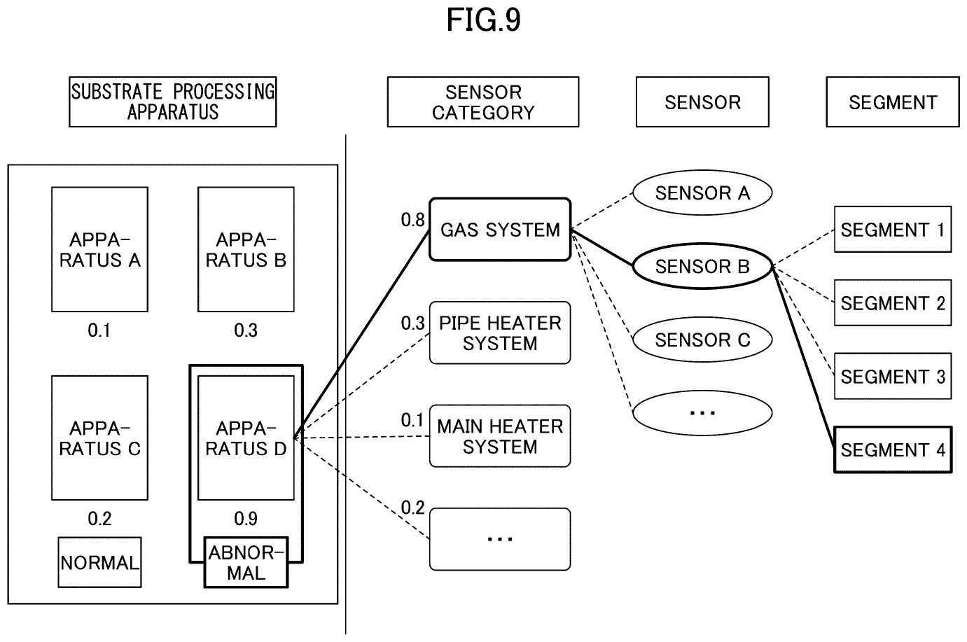

The analysis unit 303 analyzes each of the substrate processing apparatuses at a plurality of analysis levels based on the log data for each of the segments, and analyzes the inter-apparatus difference between the plurality of substrate processing apparatuses. FIGS. 8 and 9 are diagrams illustrating examples of abnormality determination based on analysis results at analysis levels.

For example, as illustrated in FIGS. 8 and 9, the analysis unit 303 analyzes the log data at four levels including the level of the substrate processing apparatus, the level of the sensor category, the level of the sensor, and the level of the segment (step).

When analyzing the log data at the level of the segment where the analysis level is the lowest, the analysis unit 303 compares and analyzes the log data for each of the segments, which is the smallest unit of the log data.

When analyzing the log data at the level of the sensor among the analysis levels, the analysis unit 303 compares and analyzes the log data for all the segments for each of the sensors. For example, in the examples of FIGS. 8 and 9, the log data for all the segments of the sensor A, the log data for all the segments of the sensor B, and the log data for all the segments of the sensor C are compared and analyzed. For example, the log data for all the segments of the sensor B is the log data of the segments 1 to 4. Here, the sensors A to C may be, for example, sensors configured to detect gas flow rates supplied to the three gas supply pipes 40A, 40B, and 40C of FIG. 1, and are not illustrated.

When analyzing the log data at the level of the sensor category, the analysis unit 303 compares and analyzes the log data for all the segments of all the sensors belonging to the sensor group classified by category. In FIGS. 8 and 9, the sensor category includes the categories of the gas system, the pipe heater system, and the main heater system, but is not limited to these categories.

When analyzing the log data at the level of the substrate processing apparatus 10, in the example of FIG. 8, the analysis unit 303 compares and analyzes the log data for all the segments of all the sensors of each of the substrate processing apparatuses A, B, and C and the log data of all the segments of all the sensors of a substrate processing apparatus serving as a reference (hereinafter, also referred to as a “reference device”). In the example of FIG. 9, the analysis unit 303 compares and analyzes the log data for all the segments of all the sensors of each of the substrate processing apparatuses A, B, C, and D for each apparatus. The data of the reference apparatus may be, for example, log data of all the segments of all the sensors of the substrate processing apparatus during a process in which a good process result is obtained.

A level for analyzing the inter-apparatus difference for each of the substrate processing apparatuses is defined as a first level. A level for analyzing the inter-apparatus difference for each of the sensor categories is defined as a second level. A level for analyzing the inter-apparatus difference for each of the sensors belonging to the sensor category is defined as a third level. A level for analyzing the inter-apparatus difference for each of the segments of each of the sensors is defined as a fourth level.

The analysis unit 303 performs analysis at four different levels based on the log data for each of the segments. However, the analysis unit 303 is not necessarily required to perform analysis at four different levels, and may perform analysis at least at one analysis level. However, the analysis unit 303 preferably performs analysis at least at two different analysis levels.

For example, the analysis unit 303 preferably analyzes the inter-apparatus difference in order of the first level, the second level, the third level, and the fourth level so that the analysis target level is drilled down from the substrate processing apparatus level to a detailed level.

The analysis unit 303 may quantify the analysis results of the inter-apparatus difference, and the display control unit 304 may display numerical values of the analysis results of the inter-apparatus differences.

In the example illustrated in FIG. 8, the numerical values of the analysis results of the inter-apparatus differences between the reference apparatus and the substrate processing apparatuses A, B, and C are indicated by “0.1”, “0.9”, and “0.2”. In this example, the substrate processing apparatus B having the largest inter-apparatus difference between the reference apparatus and the substrate processing apparatus has a high possibility of being “abnormal”. Therefore, while viewing the screen illustrated in FIG. 8, the user performs an operation to calculate the inter-apparatus difference by lowering the aggregate level of the log data by one via drill-down in order of the sensor category (second level), the sensor (third level), and the segment (fourth level) of the substrate processing apparatus B. With this, it can be predicted that the gas system has the largest inter-apparatus difference for each of the sensor categories in the sensor category at the second level, the sensor B has the largest inter-apparatus difference for each of the sensors at the third level, and the segment 4 having the largest inter-apparatus difference for each of the segments of the sensor B at the fourth level is the segment of the sensor having a high possibility of being “abnormal”.

As described, the display control unit 304 can display the analysis results as a graph, a table, or the like at the analysis level corresponding to a user's click operation performed on the displayed numerical value. Additionally, the display control unit 304 can display the analysis results by lowering the analysis level by one.

Here, in FIGS. 8 and 9, the display of the numerical values indicating the inter-apparatus difference for each of the sensors and the inter-apparatus difference for each of the segments is omitted.

As illustrated in FIG. 9, the analysis unit 303 may analyze the inter-apparatus differences between the substrate processing apparatuses A, B, C, and D without comparing them with the reference apparatus, and determine that the substrate processing apparatus D having the largest inter-apparatus difference has a high possibility of being “abnormal” based on the numerical values of the analysis results.

Additionally, as illustrated in FIG. 8, it is not limited to the case where one reference apparatus is designated, and the reference apparatus is compared with the substrate processing apparatus to be analyzed, but a plurality of substrate processing apparatuses normally operating may be used as a reference apparatus group, and the reference apparatus group may be compared with the substrate processing apparatus group to be analyzed. In this case, if the inter-apparatus difference between the reference apparatus group normally operating and the substrate processing apparatus group to be analyzed is large, the substrate processing apparatus group to be analyzed has a high possibility of being “abnormal”.

Additionally, a substrate processing apparatus group issuing an alarm may be used as a reference apparatus, and may be compared with the substrate processing apparatus group to be analyzed. In this case, if the inter-apparatus difference between the reference apparatus group issuing the alarm and the substrate processing apparatus group to be analyzed is large, the substrate processing apparatus group to be analyzed has a high possibility of being “normal”.

### Analysis Method

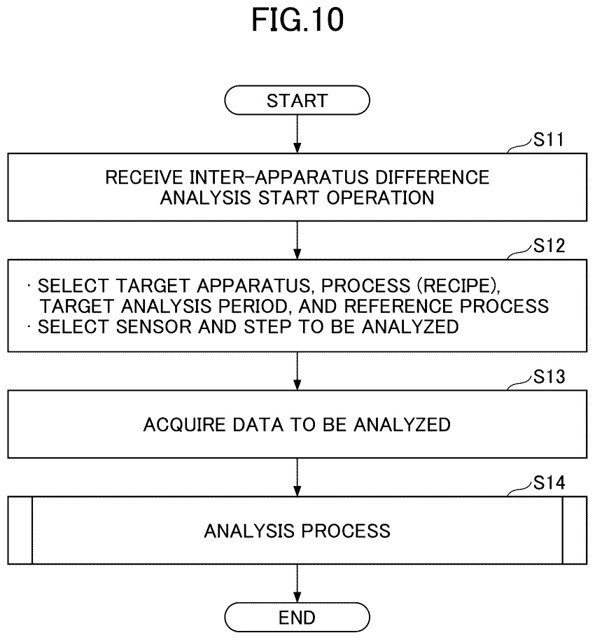

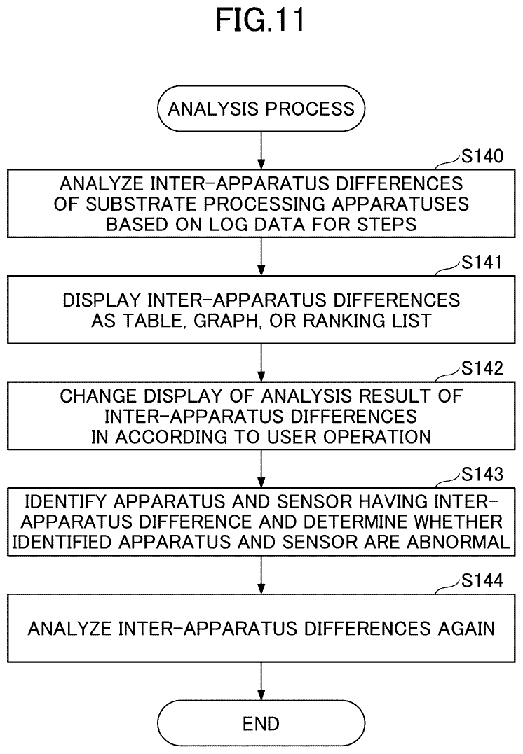

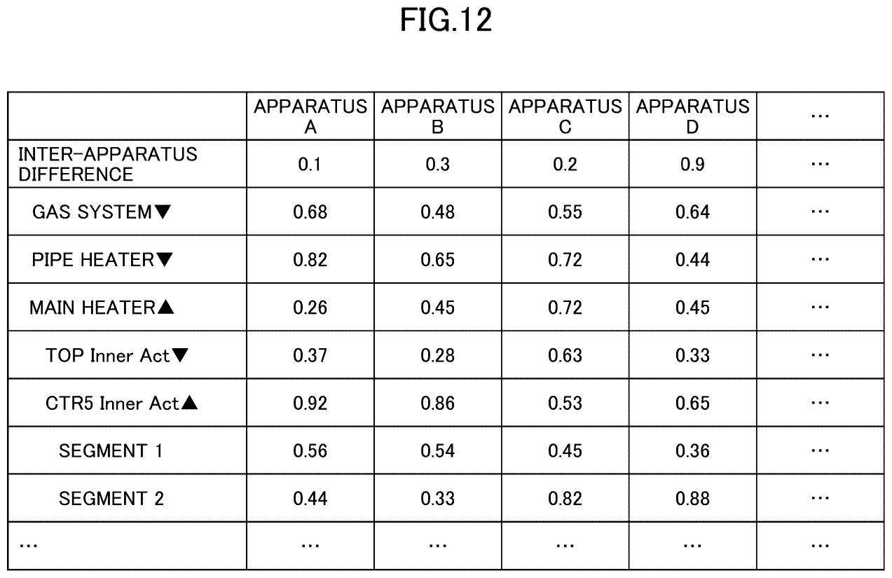

Next, an example of an analysis method according to the embodiment will be described with reference to FIGS. 10 to 16. FIG. 10 is a flowchart illustrating an example of the analysis method according to the embodiment. FIG. 11 is a flowchart illustrating an analysis process in step S14 of FIG. 10 in detail. FIGS. 12 to 16 are diagrams illustrating display examples of analysis results. The analysis method according to the present embodiment is performed by the analysis device 300. Here, before this process is performed, the preprocessing illustrated in FIG. 5 is performed, and the log data for each of the steps is stored in the data storage unit 400 for each of the sensors.

When the analysis method is started, in step S11, the input unit 301 receives an inter-apparatus difference analysis start operation by the user, and then, a program (application) for performing the analysis method is started.

Next, in step S12, the input unit 301 selects a substrate processing apparatus to be analyzed, a process (recipe), a target analysis period, and a reference process according to an input operation performed by the user. For example, the input unit 301 selects the substrate processing apparatuses A to D to be analyzed, selects a process (recipe) to be performed by the substrate processing apparatuses A to D, selects a target analysis period (YYMMDD (year, month, date)-YYMMDD), and selects a reference process. The reference process is, when there is a reference device, a process in which a good result is obtained by being performed by the reference device. When there is no reference device, it is not necessary to select the reference process. Here, in this example, description will be continued on the assumption that there is no reference device.

The input unit 301 may select a sensor and a step (segment) to be analyzed according to an input operation by the user. When the sensor and step to be analyzed are not selected by the user, all the sensors and all the steps, which are defined as initial values, are selected as the analysis targets.

Next, in step S13, the analysis unit 303 acquires the data to be analyzed from the data storage unit 400. With this, the log data for selected steps of the sensor to be analyzed is extracted.

Next, in step S14, the analysis unit 303 executes the analysis process. The analysis process will be described with reference to FIG. 11. After performing the analysis process, the analysis method ends.

### Analysis Process

In the analysis process of FIG. 11, in step S140, the analysis unit 303 analyzes the inter-apparatus difference at each of the levels from the level of the substrate processing apparatus to the detailed level, based on the log data for the selected steps of the sensor to be analyzed. For example, when the analysis target is the substrate processing apparatuses A to D, the analysis unit 303 analyzes the inter-apparatus difference for each of the substrate processing apparatuses A to D, the inter-apparatus difference for each of the sensor categories of each of the apparatuses, the inter-apparatus difference of each of the sensors belonging to each of the sensor categories, and the inter-apparatus difference for each of the steps of each of the sensors based on the log data of each of the steps.

Next, in step S141, the display control unit 304 displays the analyzed inter-apparatus differences for each of the analysis levels as a table, a graph, a ranking list or the like to be easily understood visually. However, the display control unit 304 may display the analyzed inter-apparatus differences in a form other than the table, the graph, and the ranking list.

For example, the display control unit 304 may display at least one of a histogram, a trend graph, a time-series graph, a two-dimensional graph, a summary graph, a table, or a ranking list indicating the analysis results of the inter-apparatus difference.

FIG. 12 indicates an example of the analysis results of the inter-apparatus differences at each of the analysis levels displayed by the display control unit 304. Line 1 indicates the inter-apparatus difference for each of the substrate processing apparatuses A to D. Lines 2-4 indicate the inter-apparatus differences for each of the sensor categories (the gas system, the pipe heater, and the main heater). Lines 5-6 indicate the inter-apparatus differences for each of the sensors (Top Inner Act and CTR5 Inner Act) of the main heater among the sensor categories. Lines 7-8 indicate the inter-apparatus differences of each of the segments (steps) of the sensor of CTR5 Inner Act among the sensors.

Here, a downward triangle (▾) indicates that, when the user touches the item, the analysis result at the lower level is displayed below the item. An upward triangle (▴) indicates that, when the user touches the item, the analysis result at the lower level that is displayed immediately below the item is not being displayed.

Returning to FIG. 11, in step S142, the display control unit 304 changes or adds the display of the analysis result of the inter-apparatus difference according to a user's click operation on the screen. However, the display control unit 304 may automatically display more detailed analysis results for the substrate processing apparatus having the largest inter-apparatus difference.

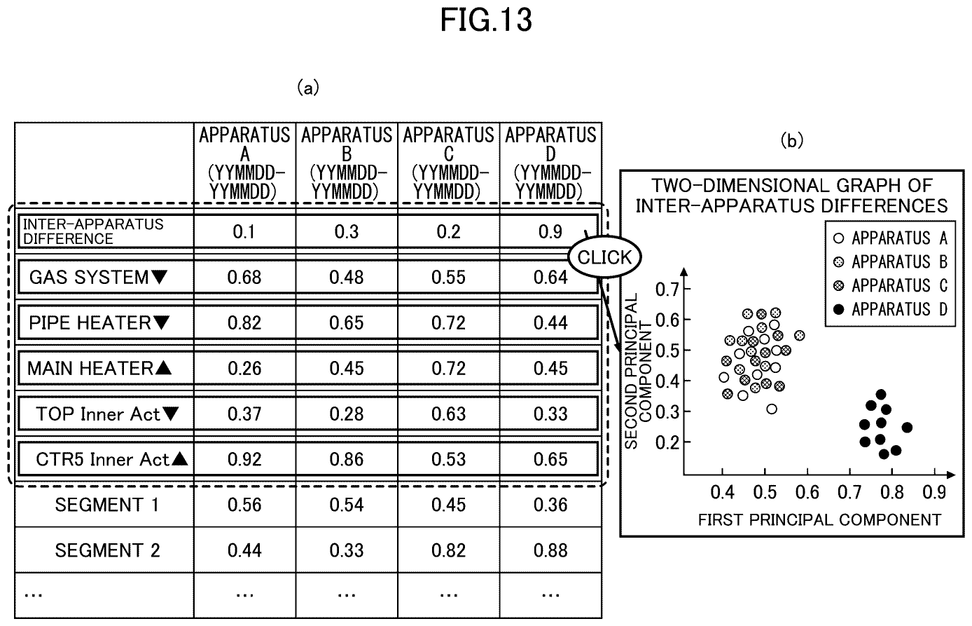

FIG. 13 illustrates an example in which, when the user clicks an item indicating the inter-apparatus difference of the apparatus D in the table in portion (a) of FIG. 13 on the screen, the display control unit 304 opens a new window in portion (b) of FIG. 13 and adds the display of a two-dimensional graph of the inter-apparatus differences of the substrate processing apparatuses A to D on the screen. The two-dimensional graph of the inter-apparatus differences is an example in which numerical values of the analysis results of the inter-apparatus differences are visualized in a graph.

For example, a principal component analysis (PCA) model projects high-dimensional data into low-dimensional data and outputs low-dimensional data of the first and second principal components in a two-dimensional space. The two-dimensional graph of the inter-apparatus difference of FIG. 13 displays the low-dimensional data of the first and second principal components in a two-dimensional space by projecting high-dimensional data included in the log data of each of the apparatuses used when calculating the inter-apparatus difference for each of the substrate processing apparatuses A to D, using the PCA model. In the example in portion (b) of FIG. 13, the data structures of the first principal component and the second principal component of the substrate processing apparatus D are separated as being unusual. Therefore, the user can notice the possibility of being “abnormal” in the substrate processing apparatus D at an early stage by checking the two-dimensional graph of the inter-apparatus differences of FIG. 13. With this, the user can properly limit the investigation range of the analysis result to the substrate processing apparatus D. As a result, the user lowers the analysis level of the log data by one via drill-down to further elaborate the analysis items. That is, the analysis result of the inter-apparatus difference can be confirmed by lowering the analysis level of the log data by one via drill-down, such as the inter-apparatus difference for each of the sensor categories of the substrate processing apparatus D, the inter-apparatus difference for each of the sensors belonging to the sensor category of the substrate processing apparatus D, or the inter-apparatus difference for each of the segments (steps) of the sensor belonging to the sensor category of the substrate processing apparatus D.

Returning to FIG. 11, next, in step S143, the analysis unit 303 identifies the substrate processing apparatus and sensor having the inter-apparatus difference by drill-down, and compares the identified substrate processing apparatus and sensor with the threshold value of the abnormality determination to determine whether the apparatus is abnormal. The display control unit 304 may display the result of the abnormality determination on the screen. Further, the analysis unit 303 may automatically perform a process for reducing the inter-apparatus difference of the substrate processing apparatus and sensor determined to be abnormal. In step S143, the analysis unit 303 may identify the substrate processing apparatus and sensor having the inter-apparatus difference according to a user's click operation.

Next, in step S144, the analysis unit 303 analyzes the inter-apparatus differences again and ends the process. The processing in step S144 need not be performed.

According to the present analysis method, as illustrated in FIGS. 12 and 13, the inter-apparatus differences of the substrate processing apparatuses can be quantified (analysis result) and visualized (screen display), so that a substrate processing apparatus performing an unusual operation can be found at an early stage. In particular, the substrate processing apparatus, sensor, and the like perform an unusual operation and that have the inter-apparatus difference can be efficiently identified by displaying the analysis results of the inter-apparatus differences for each of the substrate processing apparatuses, for each of the sensor categories, each of the sensors in the category, and each of the segments of the sensor by drill-down.

### Other Example of Visualization

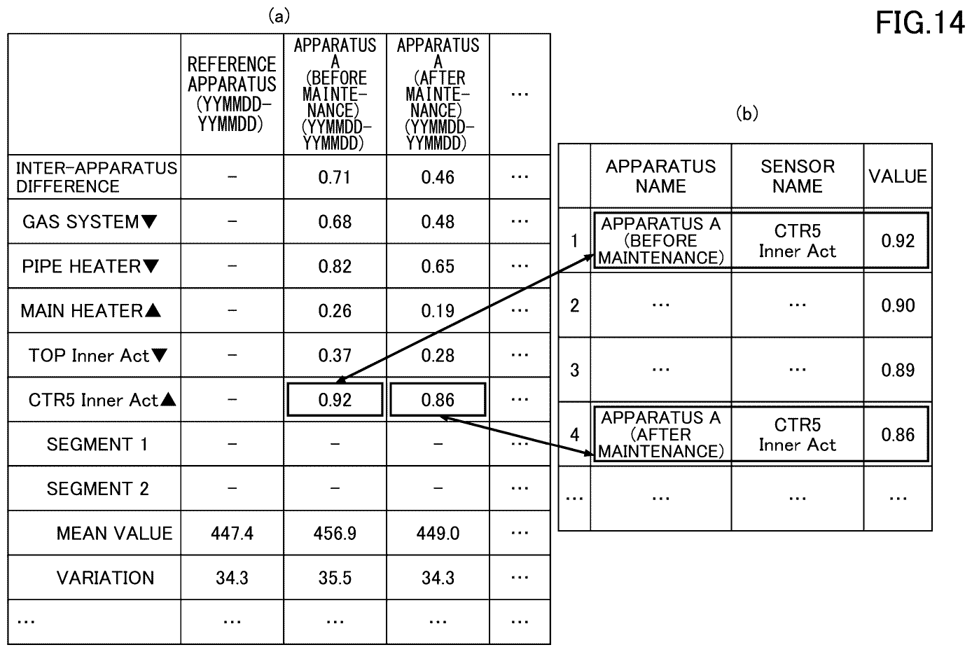

Another example of visualization (screen display) of the inter-apparatus differences of the substrate processing apparatus will be described with reference to FIGS. 14 to 16. In the above description, the inter-apparatus differences of a substrate processing apparatus are analyzed based on the log data of each apparatus. With respect to the above, in the analysis of the state change of the substrate processing apparatus, the behavior of each of the sensors is analyzed based on the log data before and after the maintenance of a single substrate processing apparatus. The analysis method is substantially the same as the above analysis method, and the state of the substrate processing apparatus is analyzed by comparing the log data for each of the segments before the maintenance with the log data for the corresponding segment after the maintenance. The analysis method is the same in that the state change of the substrate processing apparatus, the state change for each of the sensor categories, the state change of each of the sensors in the category, and the state change for each of the segments of each sensor are analyzed by drill-down.

FIG. 14 indicates a display example of the analysis results. Portion (a) of FIG. 14 indicates states of the substrate processing apparatus before and after the maintenance of the substrate processing apparatus A, states of each of the sensor categories, states of each of the sensors in the category, and states of the segments of the sensor, using the data immediately after the last maintenance as a reference. Furthermore, portion (a) of FIG. 14 indicates that the state change of the substrate processing apparatus (differences of numerical values before and after the maintenance), and the summary values of the means, the variations, and the like of the film thickness or the like of the reference apparatus and the substrate processing apparatus A before and after the maintenance are displayed.

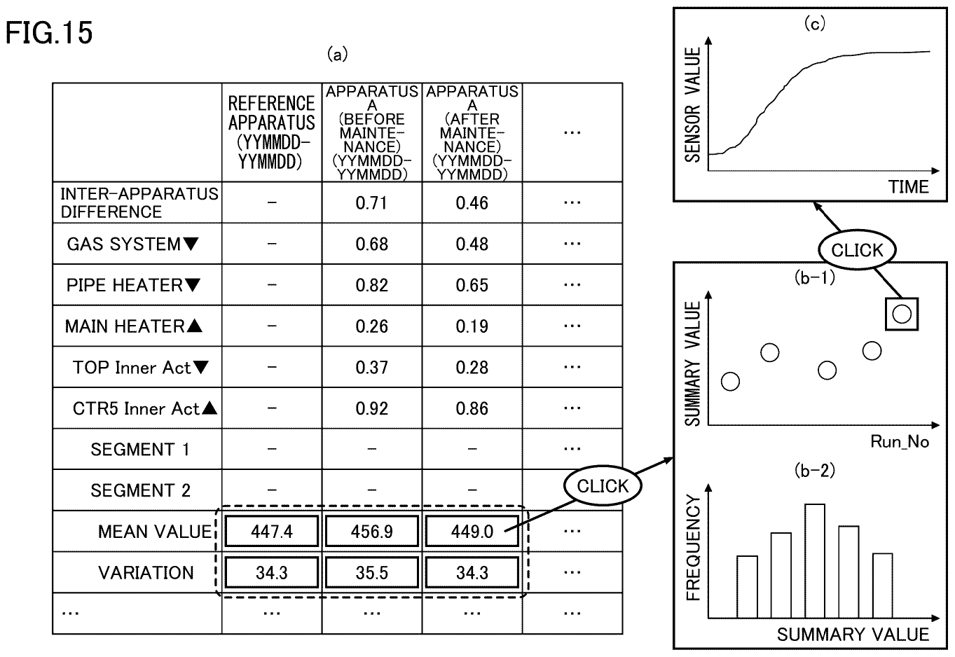

Portion (b) of FIG. 14 is a table in which values representing the states before and after the maintenance of the substrate processing apparatus A are ranked in order from largest to smallest. The rank 1 item is the value “0.92” of the sensor of CTR5 Inner Act of the substrate processing apparatus A (before the maintenance), and the value decreases as the rank decreases. In FIG. 15, when the user clicks the summary value, such as the mean or the variation in portion (a) of FIG. 15, as illustrated in portion (b-1) of FIG. 15, a summary graph or a trend graph representing a relationship between Run No (substrate processing No) and a summary value can be displayed. Additionally, as illustrated in portion (b-2) of FIG. 15, a histogram representing a frequency distribution with respect to a summary value can be displayed. Further, as illustrated in portion (b-1) of FIG. 15, when the user clicks the summary value of one of the graphs, as illustrated in portion (c) of FIG. 15, time series data before the clicked data is summarized can be displayed.

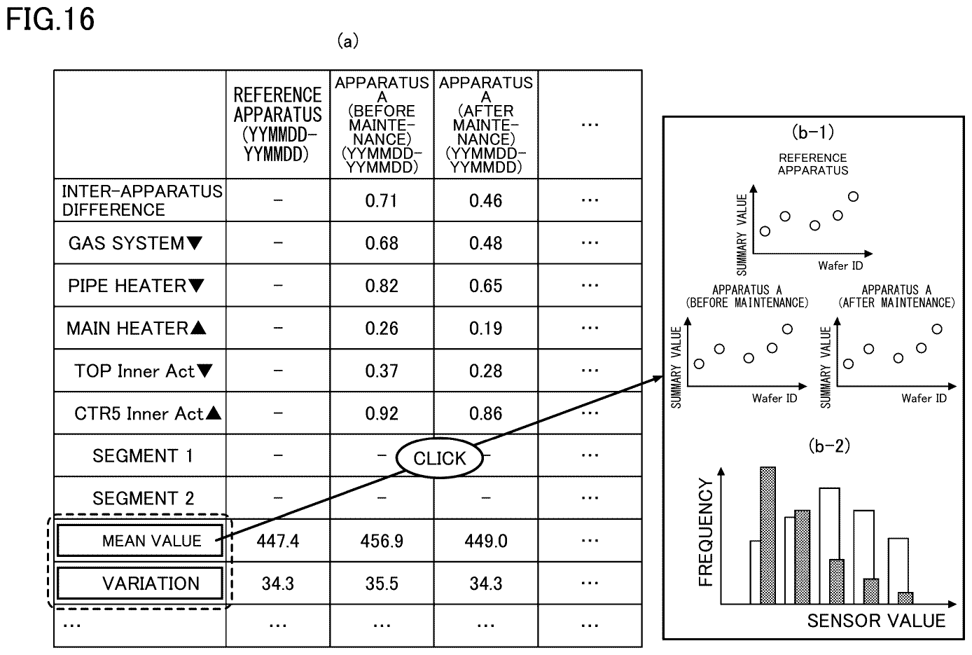

Additionally, in FIG. 16, when the user clicks the mean or the variation in portion (a) of FIG. 16, a summary graph for each apparatus illustrated in portion (b-1) of FIG. 16 and a histogram representing a frequency distribution with respect to a sensor value illustrated in portion (b-2) of FIG. 16 can be displayed.

### Analysis Timing

An example of the timing for performing the analysis method (analysis timing) is given below.
1. During mass production transfer/recipe porting
2. During start-up
3. After apparatus maintenance
4. During an alarm (a product abnormality)
5. During a normal operation

### 1. During Mass Production Transfer/Recipe Porting

In order to confirm that there is no difference between the reference apparatus (development apparatus) of the substrate processing apparatus and the mass production transfer apparatus (mass production apparatus of the substrate processing apparatus) during mass production transfer, that is, whether the reference apparatus and the mass production transfer apparatus operate differently, the inter-apparatus difference between the reference apparatus and the mass production transfer apparatus is calculated using the analysis method. With this, the inter-apparatus differences linked to the device individual difference between sensors, the part individual difference, the assembly error, the factory force difference, and the process result can be analyzed.

During recipe porting, after creating a recipe in the development apparatus, the process is performed using the same recipe in the mass production transfer apparatus, and it is confirmed whether the process result (performance) that is the same as that in the development apparatus can be obtained. Also at this time, the inter-apparatus difference between the reference apparatus and the mass production transfer apparatus is calculated using the analysis method.

### 2. During Start-Up

In order to confirm whether there is any substrate processing apparatus performing an unusual operation among the substrate processing apparatuses immediately after start-up, the inter-apparatus differences of multiple substrate processing apparatuses immediately after start-up are compared using the analysis method. The reference apparatus may or may not be used. With this, the inter-apparatus differences linked to the individual device difference between sensors, the individual part difference, the assembly error, the factory force difference, and the process result can be analyzed.

### 3. After Apparatus Maintenance

After the maintenance of the substrate processing apparatus, in order to confirm that the maintenance is carried out correctly, the difference with the data immediately after the last maintenance is compared by the analysis method, using the data immediately after the last maintenance as a reference. With this, the inter-apparatus differences linked to the device individual difference between sensors, the part individual difference, the part deterioration, the shift of the sensor value, the assembly error, the factory force difference, and the process result can be analyzed.

### 4. During an Alarm (a Product Abnormality)

In order to identify the cause of the abnormality occurrence, the substrate processing apparatus operating normally is used as a reference apparatus, and the substrate processing apparatus issuing an alarm is compared with the reference apparatus, using the analysis method, and the inter-apparatus difference with the normal apparatus is compared.

With this, the inter-apparatus differences linked to the device individual difference between sensors, the part deterioration, the shift of the sensor value, the assembly error, the factory force difference, and the process result can be analyzed.

### 5. During a Normal Operation

The inter-apparatus differences of the substrate processing apparatuses operating normally are compared using the analysis method when idle or the like. No reference apparatus need be used. This is performed regularly or irregularly. With this, the inter-apparatus differences linked to the device individual difference between sensors, the part deterioration, the shift in the sensor value, the factory force difference, and the process result can be analyzed.

### Effect

According to the above-described analysis method, a person who has no knowledge of the substrate processing apparatus can perform analysis without going through a process of narrowing down the sensors to some extent before the analysis, and can detect a substrate processing apparatus or sensor having an individual difference (inter-apparatus difference) or having a state change, and can confirm a trend chart and summary data of the sensor.

Additionally, according to the analysis method, not only a specific unit such as a temperature sensor but also a group of all sensors in the substrate processing apparatus can be collectively used for inter-apparatus difference analysis.

Furthermore, the time and labor required to manually select the sensor to be analyzed from among the sensor group before the analysis can be reduced. Therefore, the valuable resources of a person who has knowledge of the substrate processing apparatus can be allocated to other work. Additionally, in addition to detecting the sensor causing the inter-apparatus difference, the trend chart and summary data of the sensor can be displayed and confirmed.

Additionally, the inter-apparatus difference analysis linked to the process result can be performed. Therefore, anyone can identify the inter-apparatus difference and the trouble factor, and the process results can be made uniform.

### Scoring

The analysis unit 303 may score how much elements constituting the inter-apparatus difference contribute to the inter-apparatus difference with respect to the calculation result of the inter-apparatus difference of the substrate processing apparatus.

Based on the analysis result of the inter-apparatus difference, the analysis unit 303 calculates the contribution degree representing contribution to the inter-apparatus difference for each of the substrate processing apparatuses, for each of the sensor categories, for each of the sensors, and for each of the segments of the sensor. The display control unit 304 displays the contribution degree.

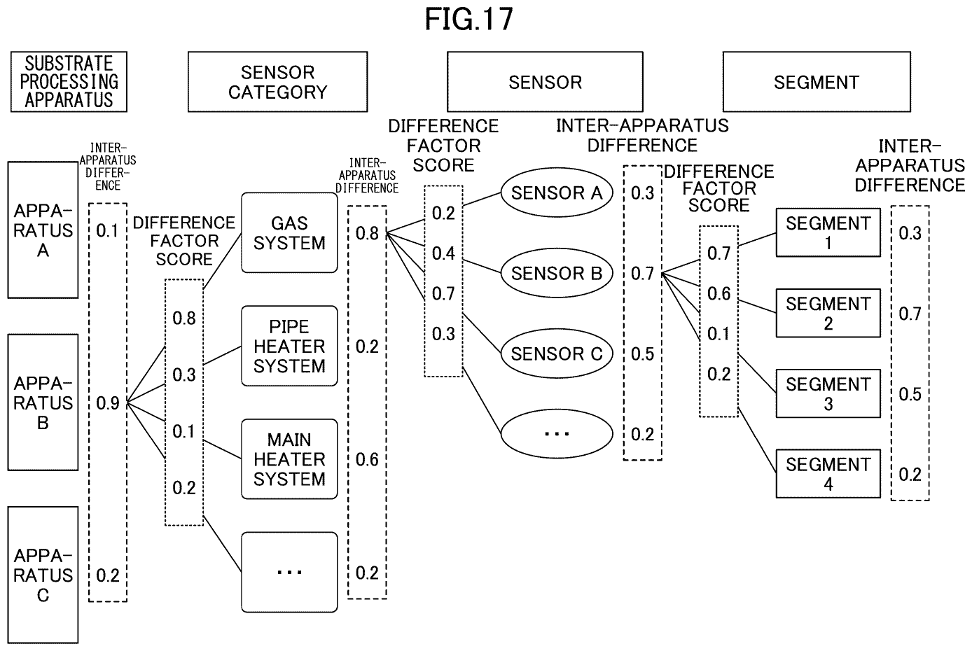

FIG. 17 indicates an example of scoring the analysis result. The inter-apparatus difference factor score (contribution degree) is displayed based on the inter-apparatus difference for each of the substrate processing apparatuses, the inter-apparatus difference for each of the sensor categories, the inter-apparatus difference for each of the sensors, and the inter-apparatus difference for each of the segments of the sensor. For example, in FIG. 17, it can be seen that the inter-apparatus difference of the substrate processing apparatus B is large, and the contribution of the gas system sensor category of the substrate processing apparatus B is large. With this, the cause of the failure can be efficiently determined.

The analysis apparatus and the analysis method according to the embodiments described above should be considered as being exemplary in all respects, and not limiting. The embodiments can be modified and improved in various ways without departing from the scope and gist of the appended claims. The matters described in the above embodiments can be constructed in other configurations without contradiction and can be combined without contradiction.

The substrate processing apparatus disclosed in the present specification is not limited to a batch type heat treatment apparatus. For example, the substrate processing apparatus 10 may be a single-wafer type apparatus for processing wafers one by one. Additionally, the substrate processing apparatus 10 may be a semi-batch type apparatus for processing several substrates in a batch. The semi-batch type apparatus may be an apparatus for causing a plurality of wafers arranged around the center line of rotation of the rotary table to rotate together with the rotary table and pass through, in order, a plurality of regions in which different gases are supplied.

The substrate processing apparatus is not limited to a film forming apparatus and may be an apparatus that can process substrates, such as an etching apparatus or a sputtering apparatus. Additionally, the substrate processing apparatus 10 is not limited to an apparatus for processing substrates using plasma and may be an apparatus for processing substrates without using plasma.

According to one aspect, the sensors of the substrate processing apparatuses can be comprehensively analyzed, and the analysis result can be visualized and displayed.

What is claimed is:

1. An analysis device comprising:
a processor; and
a memory storing program instructions that cause the processor to:
divide log data of each of sensors of sensor groups for detecting states of each of a plurality of substrate processing apparatuses into segments and store the log data divided for each of the segments in a data storage unit for each of the sensors;
perform an analysis on an inter-apparatus difference between the plurality of substrate processing apparatuses by analyzing each of the plurality of substrate processing apparatuses based on the log data divided for each of the segments stored in the data storage unit; and
display a result of the analysis.

2. The analysis device as claimed in claim 1, wherein the program instructions cause the processor to divide, according to a recipe in which a procedure of a process performed by the plurality of substrate processing apparatuses is described as steps, the log data of each of the sensors for each of the steps, and stores, in the data storage unit, the log data divided for each of the steps as the log data divided for each of the segments.

3. The analysis device as claimed in claim 1, wherein the program instructions cause the processor to extract features of a waveform of the log data of each of the sensors, divide the log data for each of the features of the waveform, and store, in the data storage unit, the log data divided for each of the features of the waveform as the log data for each of the segments.

4. The analysis device as claimed in claim 1, wherein the program instructions cause the processor to analyze each of the plurality of substrate processing apparatuses at a plurality of analysis levels based on the log data for each of the segments.

5. The analysis device as claimed in claim 4, wherein the program instructions cause the processor to perform, based on the log data for each of the segments, the analysis at least at two levels as the plurality of analysis levels among levels including a first level for analyzing an inter-apparatus difference for each of the plurality of substrate processing apparatuses, a second level for analyzing an inter-apparatus difference for each of sensor categories in which the sensor groups for detecting states of each of the plurality of substrate processing apparatuses are classified, a third level for analyzing an inter-apparatus difference for each of sensors belonging to each of the sensor categories, and a fourth level for analyzing an inter-apparatus difference for each of segments of each of the sensors.

6. The analysis device as claimed in claim 5, wherein the program instructions cause the processor to perform the analysis on the inter-apparatus difference in order of the first level, the second level, the third level, and the fourth level.

7. The analysis device as claimed in claim 6, wherein the program instructions cause the processor to display the result of the analysis as at least one of a graph, a table, or a list according to levels in the plurality of analysis levels.

8. The analysis device as claimed in claim 7, wherein the program instructions cause the processor to calculate a numerical value representing the result of the analysis of the inter-apparatus difference, display the numerical value of the result of the analysis of the inter-apparatus difference, and display the result of the analysis at a level corresponding to a user operation on the displayed numerical value among the plurality of analysis levels.

9. The analysis device as claimed in claim 7, wherein the program instructions cause the processor to display the result of the analysis by lowering the level in the plurality of analysis levels in order of the first level, the second level, the third level, and the fourth level.

10. The analysis device as claimed in claim 7, wherein the program instructions cause the processor to display at least one of a histogram, a trend graph, a time-series graph, a two-dimensional graph, a summary graph, a table, or a ranking list representing the result of the analysis of the inter-apparatus difference.

11. The analysis device as claimed in claim 5, wherein the program instructions cause the processor to calculate a contribution degree representing contribution to the inter-apparatus difference based on the analysis of the result of the inter-apparatus difference, and display the contribution degree.

12. An analysis device comprising:
a processor; and
a memory storing program instructions that cause the processor to:
divide log data of each of sensors of sensor groups for detecting states of a substrate processing apparatus into segments and store the log data divided for each of the segments in a data storage unit for each of the sensors;
perform an analysis on a state change between the substrate processing apparatus before maintenance and the substrate processing apparatus after the maintenance by analyzing the substrate processing apparatus based on the log data divided for each of the segments stored in the data storage unit, the log data being obtained before and after the maintenance; and
display a result of the analysis.

13. An analysis method comprising:
dividing log data of each of sensors of sensor groups for detecting states of each of a plurality of substrate processing apparatuses into segments and storing the log data divided for each of the segments in a data storage unit for each of the sensors;
performing an analysis on an inter-apparatus difference between the plurality of substrate processing apparatuses by analyzing each of the plurality of substrate processing apparatuses based on the log data divided for each of the segments stored in the data storage unit; and
displaying a result of the analysis.
